(19) United States
(12) Patent Application Publication
(10) Pub. No.: US 2007/0279255 A1
(43) Pub. Date: Dec. 6, 2007

(54) CHARACTER ENTRY AND DISPLAY METHOD FOR USE WITH A KEYPAD

(76) Inventor: Sherif Danish, Cupertino, CA (US)

Correspondence Address: DOVAS LAW P.C., 307 BAINBRIDGE STREET, PHILADELPHIA, PA, 19147, US

(21) Appl. No.: 11/738,112

(22) Filed: Apr. 20, 2007

Related U.S. Application Data
(60) Provisional application No. 60/797,833, filed on May 5, 2006.

(51) Int. Cl. H03M 11/00; H03K 17/94

(52) U.S. Cl. 341/22

(57) ABSTRACT

A character entry and display method for use with a 3×4 key array standard telephone keypad including a 1 key, a 2 key, a 3 key, a 4 key, a 5 key, a 6 key, a 7 key, an 8 key, a 9 key, and a 0 key. The entry and display method includes receiving a unique adjacent key pair sequence from the standard telephone keypad for each letter of a character set comprising A, B, C, D, E, F, G, H, I, J, K, L, M, N, O, P, Q, R, S, T, U, V, W, X, Y, and Z, and displaying a letter of the character set in response to receipt of each of the unique adjacent key pair sequences. Further provided is a character entry and display method for an electronic device, a character entry and display device, and a program product.

### CROSS REFERENCE TO RELATED APPLICATION(S)

This application claims the benefit of U.S. provisional application No. 60/797,833, filed May 5, 2006, which is incorporated by reference as if fully set forth.

### BACKGROUND

Text entry on mobile telephone numeric keypads or other electronic device keypads is used by millions of people to send SMS (Short Message Service) and email messages, manage notes, tasks and contacts, and perform other functions which require text entry. Text entry is often performed on a standard 3×4 key array standard telephone keypad having a “1” key, a “2” key, a “3” key, a “4” key, a “5” key, a “6” key, a “7” key, an “8” key, a “9” key, a “*” key, a “0” key, and a “#” key. Entered text is typically displayed on a display of the electronic device adjacent to the keypad.

A first known method for entering text using a numeric keypad of a mobile telephone or other electronic device involves using a variable number of keystrokes (e.g. 1 to 4 keystrokes) on a single key to produce a letter. This method is called “multitap”. Each key on the numeric keypad is typically imprinted with sequentially ordered letters, and the number of keystrokes is dependent on the respective sequential positioning of the letters as imprinted on the keys. For example, the letter sequence “ABC”, is typically located on the “2” key. To enter a letter “A”, the “2” key is typically pressed once because it is in the first position of the letter sequence. To enter a letter “B”, the “2” key is pressed twice because “B” is located in the second position of the letter sequence. The letter sequence “PQRS”, is typically located on the “7” key. Accordingly, to enter the letter “S”, the “7” key is pressed four times. After each pressing of a given key, a letter appears on the display of the device. When a first desired letter appears on the display, the user discontinues pressing the given key and moves to the key on which the next desired letter appears, or the waits until a cursor advances on the display such that the given key can be pressed again to display a second desired letter adjacent to the first desired letter. In many mobile telephone products, manufacturers incorporate special letters and other characters that can be entered on a given key in addition to the letters that appear labeled on a key. These special letters or other characters are entered by pressing a key more than the 3 or 4 times required to enter the letters that are labeled on each key. For example, to enter the letter “e” on some devices, the “3” key, which may be labeled “DEF” must be pressed 5 or 6 times. The main disadvantages of this method are:
The number of keystrokes required to enter a letter is variable, so the user must count the keystrokes carefully and/or watch the display, which requires user computation, slowing down the entry process.
If the user enters a key sequence too fast, he or she often skips the desired letter and has to continue pressing the key in order to cycle through the characters until the desired letter appears again.
If the user enters the key sequence too slowly, the cursor may advance before a desired letter has been selected.
If the user wants to enter a second letter that is on the same key as a previously entered first letter, the user must wait for the cursor to advance after entering the first letter.

The multitap method therefore causes a user “time pressure stress” in two ways. Firstly, users must enter the key sequence fast enough to obtain a desired letter. Otherwise, the cursor will move to the next position. Moreover, users must wait for the cursor to advance to the next position before entering a letter that is on the same key as an immediately preceeding entered letter.

A second known method involves entering two keystrokes on two separate keys per desired letter. The first keystroke is entered on a first key on which the desired letter appears, and the second keystroke is entered on a second key that represents the position of the desired letter as labeled on the first key. For example, “MNO” is typically labeled on the “6” key. Accordingly, to enter the letter “M”, the key sequence includes first the “6” key, then the “1” key, because “M” is labeled in the first position on the “6” key. To enter the letter “N”, the key sequence includes first the “6” key, then the “2” key, because “N” is labeled in the second position on the “6” key, and so on.

The main disadvantages of this method are:
It requires user computation first to determine the numeric position of the desired letter and then to determine the numeric key to press next.
It does not allow for special letters such as “é” because such characters do not appear labeled on a key of the keypad.

A third known method to enter text involves use of an integrated dictionary. A popular version of software used for implementing this method is called T9, which allows users to compose words stored in a digital dictionary. A user may press a single time a key having one of the letters desired by a user labeled thereon. A processor within the device implementing the T9 program uses a dictionary to determine possible words corresponding to a key sequence entered by a user, wherein each of the keystrokes represents a single letter. One or more possible words associated with a given key sequence, as determined by the dictionary, are displayed by the device.

The main disadvantages of this method are:
Words that are not in the dictionary such as proper nouns must be entered using other entry methods.
Abbreviations, which are commonly used in SMS and email, cannot be entered.
Many words, especially short words, are generated with the same key sequence. For example, a sequence consisting of a “4” key (labeled “GHI”) input followed by a “6” key (labeled “MNO”) input would generate the word “GO” and the word “IN”. The processor of the device would be unable to determine the desired word without further input by a user. Accordingly, a browse feature is typically provided to allow a user to scroll through generated words shown on a display.
Some implementations of T9 require a user to depress and hold a key for a predetermined time, for example 1 second or more, to enter the digit labeled on that key, a process which can be lengthy and frustrating especially when entering a long string of numbers, for example a phone number.

Other methods in addition to those discussed above are known. However, all of the known methods suffer from at least some of the deficiencies discussed above. Specifically, the known methods require some level of computation, non-intuitive learning, memorization, and/or waiting to achieve text entry and display. It would be desirable to provide a method for character entry and display which eliminates the above-stated deficiencies, allowing a user to enter text into a device, for example a mobile telephone, without significant computation, learning, memorization or waiting.

### SUMMARY

The present invention provides a character entry and display method for use with a 3×4 key array standard telephone keypad including a 1 key, a 2 key, a 3 key, a 4 key, a 5 key, a 6 key, a 7 key, an 8 key, a 9 key, and a 0 key. The entry and display method includes receiving a unique adjacent key pair sequence from the standard telephone keypad for each letter of a character set comprising A, B, C, D, E, F, G, H, I, J, K, L, M, N, O, P, Q, R, S, T, U, V, W, X, Y, and Z, and displaying a letter of the character set in response to receipt of each of the unique adjacent key pair sequences.

The present invention further provides a character entry and display method for an electronic device. The method includes providing a keypad having a plurality of keys, a processor connected to the keypad, and a memory connected to the processor which stores a plurality of characters including a plurality of letters. The memory also stores a unique key sequence identifier for each of the plurality of characters, wherein each of the plurality of letters corresponds to a unique one of a plurality of adjacent key pair sequences, and wherein the plurality of letters comprise a complete language letter set. A display is also provided connected to the processor. The processor receives the plurality of adjacent key pair sequences, wherein each of the plurality of adjacent key pair sequences includes a consecutive input from two adjacent ones of the plurality of keys. The processor associates the plurality of letters respectively with the plurality of adjacent key pair sequences, and the display displays the plurality of letters respectively associated with the plurality of adjacent key pair sequences.

The present invention further provides a character entry and display device including a 3×4 key standard telephone keypad comprising a 1 key, a 2 key, a 3 key, a 4 key, a 5 key, a 6 key, a 7 key, an 8 key, a 9 key, and a 0 key. A processor is connected to the keypad and is configured to receive a plurality of adjacent key pair sequences, wherein each of the plurality of adjacent key pair sequences includes a consecutive input from two adjacent ones of the plurality of keys. A memory is connected to the processor which stores a plurality of characters including a plurality of letters, and which stores a unique key sequence identifier for each of the plurality of characters, wherein each of the plurality of letters corresponds to one of a plurality of adjacent key pair sequences, and wherein the plurality of letters include a complete language letter set. Wherein, the processor is configured to associate the plurality of letters respectively with the plurality of adjacent key pair sequences. A display is connected to the processor and is configured to display the plurality of letters respectively associated with the plurality of adjacent key pair sequences.

The present invention further provides a program product including a computer readable medium including instructions. The instructions are operable to enable an electronic device including a display and a 3×4 key array standard telephone keypad to perform a procedure including receiving a unique adjacent key pair sequence from the standard telephone keypad for each letter of a character set including A, B, C, D, E, F, G, H, I, J, K, L, M, N, O, P, Q, R, S, T, U, V, W, X, Y, and Z, and displaying with the display a letter of the character set in response to receipt of each of the unique adjacent key pair sequences.

### BRIEF DESCRIPTION OF THE DRAWING(S)

The foregoing Summary as well as the following detailed description will be readily understood in conjunction with the appended drawings which illustrate preferred embodiments of the invention. In the drawings:

FIG. 1 is an elevation view of a mobile telephone useful for implementing a character entry and display method according to a preferred embodiment of the present invention.

FIG. 2 is a schematic diagram showing functional components of the mobile telephone of FIG. 1 and data transmission paths among the functional components pursuant to a preferred embodiment of the present invention.

FIG. 3 is a flow chart showing the character entry and display method according to a preferred embodiment of the present invention.

FIG. 4 is an example of a first preferred visual aid for display during the character entry and display method according to a preferred embodiment of the present invention.

FIG. 5 is an example of a second preferred visual aid for display during the character entry and display method according to a preferred embodiment of the present invention.

FIG. 6 is an elevation view of an alternative preferred keypad according to a preferred embodiment of the present invention.

### DETAILED DESCRIPTION OF THE PREFERRED EMBODIMENT(S)

Certain terminology is used in the following description for convenience only and is not limiting. The words “right,” “left,” “top,” and “bottom” designate directions in the drawings to which reference is made. The words “a” and “one” are defined as including one or more of the referenced item unless specifically stated otherwise. This terminology includes the words above specifically mentioned, derivatives thereof, and words of similar import. The phrase “at least one” followed by a list of two or more items, such as A, B, or C, means any individual one of A, B or C as well as any combination thereof.

The preferred embodiments of the present invention are described below with reference to the drawing figures where like numerals represent like elements throughout.

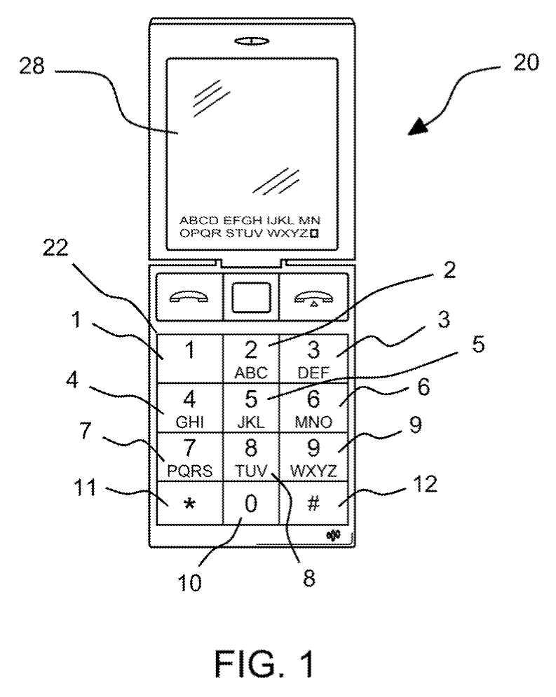

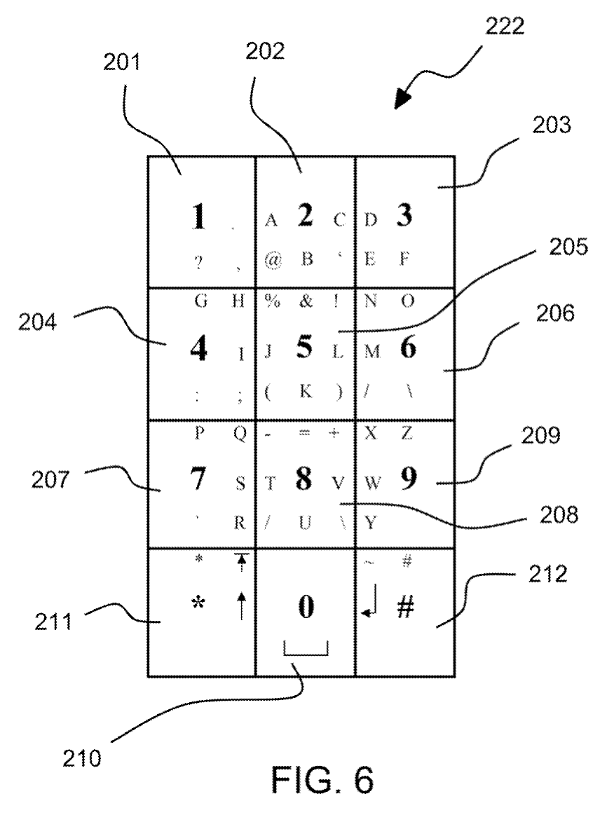

In the following description, a 3×4 key array standard telephone keypad is a keypad including a 1 key, a 2 key, a 3 key, a 4 key, a 5 key, a 6 key, a 7 key, an 8 key, a 9 key, a 0 key, and two additional keys such as non-digit keys, for example a * key and a key, positioned as shown in FIGS. 1 and 6, with or without number or letter labeling.

In the following description, a character set including the letters A, B, C, D, E, F, G, H, I, J, K, L, M, N, O, P, Q, R, S, T, U, V, W, X, Y, and Z represents a character set including the upper case letters shown or the lower case letters a, b, c, d, e, f, g, h, i, j, k, l, m, n, o, p, q, r, s, t, u, v, w, x, y, and z. Whereby for example whenever the letter “A” is indicated herein, it is meant to indicate either the upper case letter “A” or the lower case letter “a”.

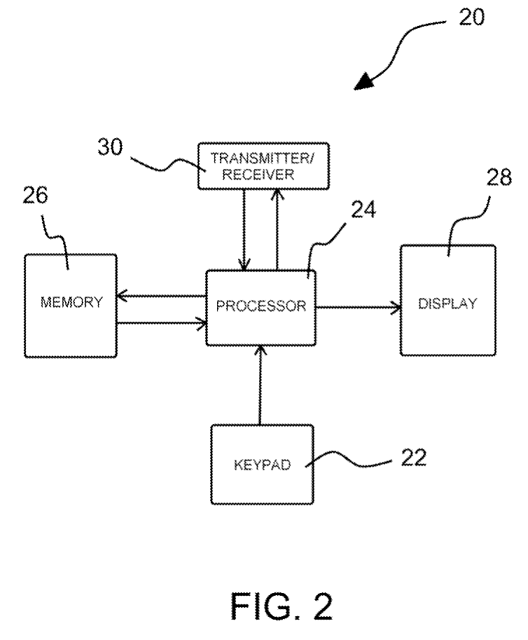

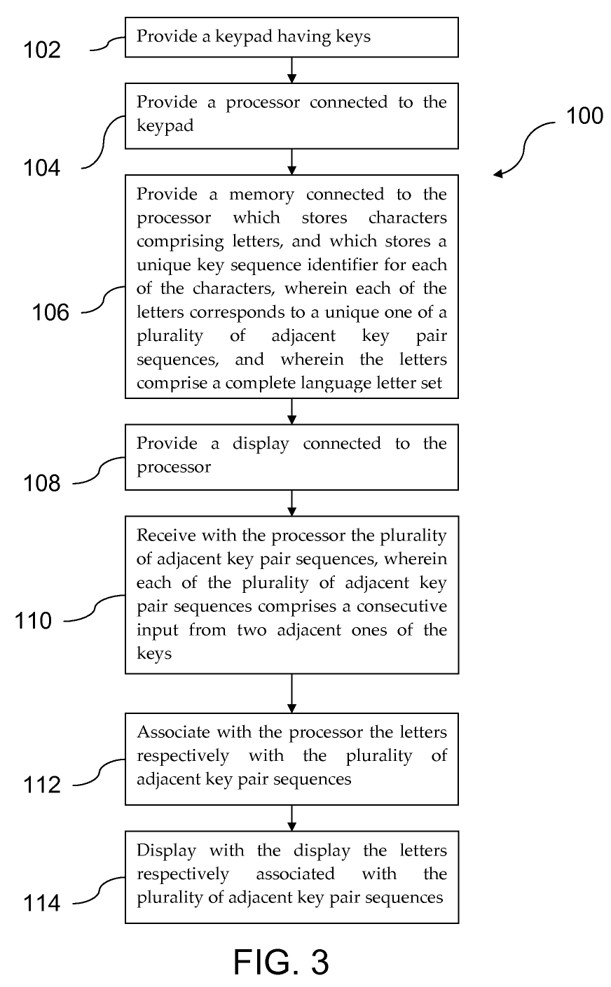

Referring to FIGS. 1 through 3, a mobile telephone 20 is shown useful for implementing a character entry and display method 100 according to a preferred embodiment of the present invention. While a mobile telephone is shown, alternatively, any suitable electronic device allowing for character entry and display may be used to implement the character entry and display method 100 according to the preferred embodiment of the present invention. FIG. 2 is a schematic diagram showing functional components of the mobile telephone 20 of FIG. 1, and data transmission paths among the functional components, pursuant to the preferred embodiment of the present invention.

The mobile telephone 20 includes a keypad 22 having a plurality of keys arranged as a 3×4 key array standard telephone keypad including a “1” key 1, a “2” key 2, a “3” key 3, a “4” key 4, a “5” key 5, a “6” key 6, a “7” key 7, an “8” key 8, a “9” key 9, a “0” key 10, a “*” key 11, and a “#” key 12. A processor 24 is connected to the keypad 22 and is configured to receive inputs from the keypad 22. A memory 26 is connected to the processor 24 which stores a plurality of characters including a plurality of letters, and which stores a unique key sequence identifier for each of the plurality of characters, wherein each of the plurality of letters corresponds to one of a plurality of adjacent key pair sequences, and wherein the plurality of letters comprise a complete language letter set. A display 28 connected to the processor 24 is configured to display transmitted data from the processor 24. A transceiver 30 including a transmitter and receiver is preferably provided connected to the processor 24 for sending data from and receiving data to the mobile telephone 20.

The method 100 is described as follows with reference to the mobile telephone 20 shown in FIGS. 1 and 2. It will be recognized by those skilled in the art that the method 100 may be implemented with any suitable character entry and display device. The method 100 preferably includes providing the keypad 22 including the keys 1, 2, 3, 4, 5, 6, 7, 8, 9, 10, 11, 12 (step 102), and providing the processor 24 connected to the keypad 22 (step 104). Alternatively, any suitable keypad configuration may be provided with keys arranged in any suitable manner.

The memory 26 is preferably provided connected to the processor 24 (step 106). The memory 26 stores characters including letters, and stores a unique key sequence identifier for each of the characters, wherein each of the letters corresponds to a unique one of a plurality of adjacent key pair sequences, and wherein the letters comprise a complete language letter set. A complete language letter set as defined herein is a group of letters including all of the letters for a given language. Preferably the memory 26 stores a complete language letter set of the English language, which includes A, B, C, D, E, F, G, H, I, J, K, L, M, N, O, P, Q, R, S, T, U, V, W, X, Y, and Z, including all lower case variants thereof. Alternatively, the memory may store a complete language letter set of any language. For example a complete language letter set of the Swedish language can be stored, which includes A, B, C, D, E, F, G, H, I, J, K, L, M, N, O, P, Q, R, S, T, U, V, W, X, Y, Z, Å, Ä, and Ö. The characters stored in the memory also preferably include non-letter characters, for example the non-letter characters shown in Table 1 below, including period (.), comma (,), question mark (?), space, and digits (1, 2, 3, 4, 5, 6, 7, 8, 9, or 0). Moreover function instructions can be stored including but not limited to: next line, shift, shift lock/unlock, and instructions to display a plurality of special characters using the display 28 to permit user selection.

The processor 24 receives the plurality of adjacent key pair sequences, wherein each of the plurality of adjacent key pair sequences includes a consecutive input from two adjacent ones of the keys 1, 2, 3, 4, 5, 6, 7, 8, 9, 10, 11, 12 (step 110). The processor 24 thereafter associates the letters respectively with the plurality of adjacent key pair sequences (step 112). Table 1 shows the preferred adjacent key pair sequences, in terms of consecutive inputs from the keys 1, 2, 3, 4, 5, 6, 7, 8, 9, 10, 11, 12, associated with letters of the English language letter set. Table 1 further lists the preferred adjacent key pair sequences associated with non-letter characters as well as functions. For clarity, the * key 11 and the # key 12 are listed as * and # respectively in the table.

TABLE 1

| Character/ | |
|---|---|
| Function | Key Input(s) |
| A | 21 |
| B | 24, 25, 26 |
| C | 23 |
| D | 32 |
| E | 35 |
| F | 36 |
| G | 41, 47 |
| H | 42, 48 |
| I | 45 |
| J | 54 |
| K | 51, 52, 53, 57, 58, 59 |
| L | 56 |
| M | 65 |
| N | 62, 68 |
| O | 63, 69 |
| P | 74, 7* |
| Q | 75 or 70 |
| R | 70 or 75 |
| S | 78 |
| T | 87 |
| U | 84, 85, 86, 8*, |
| | 80, 8# |
| V | 89 |
| W | 98 |
| X | 95 or 90 |
| Y | 90 or 95 |
| Z | 96, 9# |
| Period | 12 |
| Comma | 15 |
| ? | 14 |
| Digits | Digit key |
| | twice |
| Space | 0 |
| Next line | #0 |
| Shift | *0 |
| Shift lock/ | *7, *8 |
| unlock | |
| Special | ** |
| Character | |
| table | |

Referencing the system set forth in Table 1, an “A” character is preferably associated with the adjacent key pair sequence entered as a consecutive input from the 2 key 2 followed by the 1 key 1. A “B” character is associated with the adjacent key pair sequence entered as a consecutive input from one of: the 2 key 2 followed by the 1 key 1, the 2 key 2 followed by the 5 key 5, and the 2 key 2 followed by the 6 key 6. A “C” character is associated with the adjacent key pair sequence entered as a consecutive input from the 2 key 2 followed by the 3 key 3. A “5” character is associated with the adjacent key pair sequence entered as two consecutive inputs from the 5 key 5. A table of other characters for display by the display 28 allowing a user to select additional “special” characters may be associated with the adjacent key pair sequence entered as two consecutive inputs from the * key 11.

As set forth in the system of Table 1, a unique diagonally adjacent key pair sequence is preferably associated to each of the B, E, H, K, N, Q, R, U, X, and Y characters, meaning that each of the consecutive inputs entered to form a respective one of the key pair sequences includes two keys which are diagonal to each other. It follows that a unique vertically adjacent key pair sequence is preferably associated to each of the F, G, O, P, and Z characters, meaning that each of the consecutive inputs entered to form a respective one of the key pair sequences includes two keys which are vertical to each other. A unique vertically adjacent sequence may also be associated with each of the B, K and U characters in addition to the respective diagonally adjacent key pair sequences associated thereto, as shown in Table 1. It further follows that a unique horizontally adjacent key pair sequence is associated to each of the A, C, D, I, J, L, M, S, T, V, and W characters, meaning that each of the consecutive inputs entered to form a respective one of the key pair sequences includes two keys which are horizontal to each other.

While not wishing to be limited by a particular theory of functionality, the system set forth in Table 1 allows a user to make use of the letter labeling typical of a 3×4 key array standard telephone keypad, as shown on the mobile phone 20, to assist the user with intuitively determining the key pair sequence associated with each letter of the character set. For example, the 2 key 2 is labeled “ABC” consistent with standard labeling on most mobile telephones. Since the letter A is labeled on the leftmost side of the 2 key 2, a user may intuitively determine that the first key input of the key pair sequence associated with A is on the 2 key 2, and the second key input is to the left of the 2 key 2, i.e. the 1 key 1. As another example, the 3 key 3 is labeled “DEF”. Since the letter F is labeled on the rightmost side of the 3 key 3, and no key resides to right of the 3 key 3, a user may intuitively determine that the first key input of the key pair sequence associated with F is on the 3 key 3 and the second key input is below the 3 key 3, i.e. the 6 key 6. As a last example, the 5 key 5 is labeled “JKL”. Since the K is labeled in the center of the 5 key 5, a user may intuitively determine that the first key input of the key pair sequence associated with K is on the 5 key 5, and the second key input is neither left nor right, but is diagonal or vertical to the 5 key 5, i.e. the 1 key 1, 2 key 2, 3 key 3, 7 key 7, 8 key 8, or 9 key 9. As such, the method 100 may be implemented with a standard mobile telephone keypad having typical keypad labeling without making any modification. Moreover, software which enables the method 100 may be loaded on standard mobile telephone devices without physically reconfiguring the telephone devices or requiring special unconventional keypad labeling.

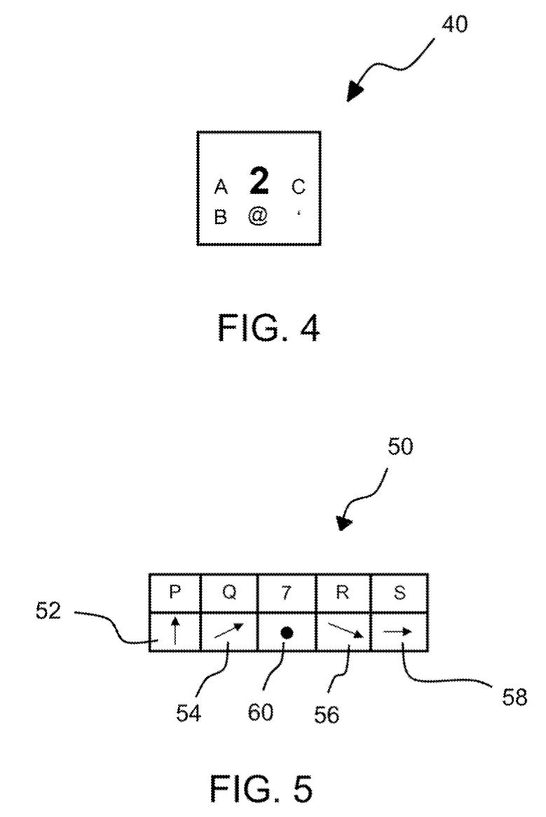

As set forth in the system of Table 1, certain keys such as the “B” character may be associated with more than one adjacent key pair sequence. Alternatively, the method 100 may permit assigning only one adjacent key pair sequence to each character, with the remaining unused adjacent key pair sequences being used for special letter or non-letter characters, for example “@” and “′”, as described below with reference to FIG. 4. Also, letter pairs Q and R and letter pairs X and Y may be respectively associated with identical alternative adjacent key pair sequences, as shown in Table 1. For example, for each letter Q and R, one adjacent key pair sequence must be selected by the user or otherwise determined such that a conflicting adjacent key pair sequence does not result for Q and R. A user may choose the key sequence including the input 7 key 7 plus 5 key 5 for the Q, and 7 key 7 plus 0 key 10 for the R, or vice versa. As such, the method 100 preferably permits a user to program the mobile telephone 20, or other electronic device, to instruct the processor 24 as to which letter or non-letter character to associate with each adjacent key pair sequence.

The display 28 is provided connected to the processor (step 108). The display 28 displays the letters or other characters respectively associated with the plurality of adjacent key pair sequences (step 114) as communicated by the processor 24. Preferably the display 28 also displays a cursor rectangle or other suitable cursor, as shown in FIG. 1. The cursor rectangle is preferably displayed after a first key input is entered to indicate that a second key input is required. The display 28 may further display a visual aid in addition to the cursor rectangle indicating available ones of letters or other characters and ones of the plurality of keys 1, 2, 3, 4, 5, 6, 7, 8, 9, 10, 11, 12 useful as the second input to create the unique adjacent key pair sequence respectively associated with the available ones of the characters of the character set.

FIG. 4 shows a first preferred example visual aid 40 to be displayed by the display 28. The first preferred example visual aid 40 may be displayed by the display 28 after input of the 2 key 2, to indicate which remaining keys corresponding to the second input should be pressed to obtain a desired character. The visual aid 40 includes an “A” character positioned on a middle left portion thereof, a “C” character positioned on a middle right portion thereof, a “B” character positioned on a lower left portion thereof, an “@” character positioned on a lower middle portion thereof, and a character positioned on a lower right portion.

The “A” character is positioned on the middle left portion of the visual aid 40 to remind a user that after inputting the 2 key 2, the next consecutive input associated with an “A” character is immediately horizontal to the left of the 2 key 2, i.e. the 1 key 1. The “B” character is positioned on the lower left portion of the visual aid 40 to remind a user that after inputting the 2 key 2, the next consecutive input associated with a “B” character is immediately diagonally below and to the left of the 2 key 2, i.e. the 4 key 4. The “C” character is positioned on the middle right portion of the visual aid 40 to remind a user that after inputting the 2 key 2, the next consecutive input associated with a “C” character is immediately horizontal to the right of the 2 key 2, i.e. the 3 key 3. The “@” character is positioned on the lower middle portion of the visual aid 40 to remind a user that after inputting the 2 key 2, the next consecutive input associated with a “@” character is immediately vertically below the 2 key 2, i.e. the 5 key 5. The “′” character is positioned on the lower right portion of the visual aid 40 to remind a user that after inputting the 2 key 2, the next consecutive input associated with an “′” character is immediately diagonally below and to the right of the 2 key 2, i.e. the 6 key 6. The remaining keys of a standard 3×4 key array standard telephone keypad may correspond to displayed visual aids of the same type to allow a user to intuitively implement the method 100 according to the preferred embodiment of the present invention. The relative positioning of each character on the visual aid 40 helps a user to intuitively determine the key inputs for each adjacent key pair sequence associated with a particular character.

Alternatively, the visual aid 40 can be provided as a key label, for example the visual aid 40 may replace the labeling shown on 2 key 2 in FIG. 1, as shown on a 2 key 202 on an alternative keypad 222 of FIG. 6, to assist a user with character entry. FIG. 6 shows the alternative keypad 222 having keys 201, 202, 203, 204, 205, 206, 207, 208, 209, 210, 211, 212 with labeling which helps a user to intuitively determine adjacent key pair sequences in the manner described above with reference to the visual aid 40 of FIG. 4.

FIG. 5 shows a second preferred example visual aid 50. Referencing the system set forth in Table 1, the visual aid 50 as shown including the letters P, Q, R, and S, and the number 7 may be displayed by the display after input of the 7 key 7, to indicate which remaining keys corresponding to the second input should be pressed to obtain a desired character. The visual aid 50 uses a first arrow 52, a second arrow 54, a third arrow 56 and a fourth arrow 58, and a dot 60 such that a user may intuitively determine the location of the second input without looking at the keys. The first arrow 52 indicates that the second key (4 key 4) of the adjacent key pair sequence associated with the P is directly vertically above the first key (7 key 7) of the adjacent key pair sequence. The second arrow 54 indicates that the second key (5 key 5) of the adjacent key pair sequence associated with the Q is directly diagonally above and to the right of the first key (7 key 7) of the adjacent key pair sequence. The third arrow 56 indicates that the second key (0 key 0) of the adjacent key pair sequence associated with the R is directly diagonally below the first key (7 key 7) of the adjacent key pair sequence. The fourth arrow 58 indicates that the second key (8 key 8) of the adjacent key pair sequence associated with the S is directly horizontally right of the first key (7 key 7) of the adjacent key pair sequence. The dot 60 indicates that the second key (7 key 7) of the adjacent key pair sequence associated with the 7 is the same as the first key (7 key 7) of the adjacent key pair sequence. It should be mentioned that while the visual aids 40, 50 are effective in assisting a user with character entry, with some experience a user may quickly perform character entry according to the preferred embodiment of the present invention without such visual aids.

Preferably, characters, including letters or non-letters, as described above are associated and displayed substantially immediately after the last input of a key sequence is received by the processor, requiring no further user input. Referencing the preferred system set forth in Table 1, each of the characters and functions, with the exception of “space”, are associated with a key sequence including consecutive inputs from exactly two adjacent ones of the keys on the keypad 22, i.e. an adjacent key pair sequence. This permits the processor 24 to perform the association of the characters (or functions) without additional key inputs, user waiting or requiring the use of the display for additional user selection. The “space” character requires only a single input from the 0 key 10, and the only other character beginning with an input of the 0 key 10 is the 0 digit, which requires two consecutive inputs from the 0 key 10. Accordingly, the processor 24 is preferably configured to perform the association of the “space” character with a single input from the 0 key 10 after the processor 24 receives an immediately subsequent input from any key which is not the 0 key 10. An exception occurs for optional special characters, wherein a pop-up table is preferably enabled by the ** key sequence (two consecutive inputs from the * key 11) such that a user may select a special character, for example $, %, or £, from the display using further inputs.

While not wishing to be limited by a particular theory of functionality, the present invention utilizes a user's brain's ability to quickly determine key sequences based on the visual topography of the telephone keypad including the visual proximity of adjacent keys, to speed character entry.

While the preferred embodiments of the invention have been described in detail above, the invention is not limited to the specific embodiments described above, which should be considered as merely exemplary. Further modifications and extensions of the present invention may be developed, and all such modifications are deemed to be within the scope of the present invention as defined by the appended claims.

What is claimed is:

1. A character entry and display method for use with a 3×4 key array standard telephone keypad comprising a plurality of keys comprising a 1 key, a 2 key, a 3 key, a 4 key, a 5 key, a 6 key, a 7 key, an 8 key, a 9 key, and a 0 key, the entry and display method comprising:
receiving a unique adjacent key pair sequence from the standard telephone keypad for each letter of a character set comprising A, B, C, D, E, F, G, H, I, J, K, L, M, N, O, P, Q, R, S, T, U, V, W, X, Y, and Z; and
displaying a letter of the character set in response to receipt of each of the unique adjacent key pair sequences.

2. The character entry and display method of claim 1, further comprising:
receiving a first one of the unique adjacent key pair sequences as a consecutive input from the 2 key and the 1 key, and displaying an “A” in response to the first one of the unique adjacent key pair sequences.

3. The character entry and display method of claim 1, further comprising:
receiving a second one of the unique adjacent key pair sequences as at least one of a consecutive input from the 2 key and the 4 key, a consecutive input from the 2 key and the 5 key, and a consecutive input from the 2 key and the 6 key, and displaying a “B” in response to the second one of the unique adjacent key pair sequences.

4. The character entry and display method of claim 1, further comprising:
receiving a third one of the unique adjacent key pair sequences as a consecutive input from the 2 key and the 3 key, and displaying a “C” in response to the third one of the unique adjacent key pair sequences.

5. The character entry and display method of claim 1, further comprising:
receiving a fourth one of the unique adjacent key pair sequences as a consecutive input first from the 3 key and then from the 2 key, and displaying a “D” in response to the fourth one of the unique adjacent key pair sequences.

6. The character entry and display method of claim 1, further comprising:
receiving a fifth one of the unique adjacent key pair sequences as a consecutive input first from the 3 key and then from the 5 key, and displaying an “E” in response to the fifth one of the unique adjacent key pair sequences; and
receiving a sixth one of the unique adjacent key pair sequences as a consecutive input first from the 3 key and then from the 6 key, and displaying an “F” in response to the sixth one of the unique adjacent key pair sequences.

7. The character entry and display method of claim 1, further comprising:
receiving a unique diagonally adjacent key pair sequence for each of the B, E, H, K, N, Q, R, U, X, and Y; and
displaying the B, E, H, K, N, Q, R, U, X, and Y in response to the receiving the unique diagonally adjacent key pair sequences.

8. The character entry and display method of claim 1, further comprising:
receiving a unique vertically adjacent key pair sequence for each of the F, G, O, P, and Z; and
displaying the F, G, O, P, and Z in response to the receiving the unique vertically adjacent key pair sequences.

9. The character entry and display method of claim 1, further comprising:
receiving a unique horizontally adjacent key pair sequence for each of the A, C, D, I, J, L, M, S, T, V, and W; and
displaying the A, C, D, I, J, L, M, S, T, V, and W in response to the receiving the unique horizontally adjacent key pair sequences.

10. The character entry and display method of claim 1, further comprising:
receiving a first one of the unique adjacent key pair sequences as a consecutive input from the 2 key and the 1 key, and displaying an “A” in response to the first one of the unique adjacent key pair sequences;
receiving a second one of the unique adjacent key pair sequences as at least one of a consecutive input from the 2 key and the 4 key, a consecutive input from the 2 key and the 5 key, and a consecutive input from the 2 key and the 6 key, and displaying a “B” in response to the second one of the unique adjacent key pair sequences;
receiving a third one of the unique adjacent key pair sequences as a consecutive input from the 2 key and the 3 key, and displaying a “C” in response to the third one of the unique adjacent key pair sequences;
receiving a fourth one of the unique adjacent key pair sequences as a consecutive input from the 3 key and the 2 key, and displaying a “D” in response to the fourth one of the unique adjacent key pair sequences;
receiving a fifth one of the unique adjacent key pair sequences as a consecutive input from the 3 key and the 5 key, and displaying an “E” in response to the fifth one of the unique adjacent key pair sequences;
receiving a sixth one of the unique adjacent key pair sequences as a consecutive input first from the 3 key and then from the 6 key, and displaying an “F” in response to the sixth one of the unique adjacent key pair sequences;
receiving a seventh one of the unique adjacent key pair sequences as at least one of a consecutive input from the 4 key and the 1 key, and a consecutive input from the 4 key and the 7 key, and displaying a “G” in response to the seventh one of the unique adjacent key pair sequences;
receiving a eighth one of the unique adjacent key pair sequences as at least one of a consecutive input from the 4 key and the 2 key, and a consecutive input from the 4 key and the 8 key, and displaying a “H” in response to the second one of the unique adjacent key pair sequences; and
receiving a ninth one of the unique adjacent key pair sequences as a consecutive input from the 4 key and the 5 key, and displaying an “I” in response to the ninth one of the unique adjacent key pair sequences.

11. The character entry and display method of claim 1, wherein the unique adjacent key pair sequence comprises a first key input and a second key input consecutive with the first key input on the keypad, the method further comprising:
after the first key input, displaying a visual aid indicating available ones of the letters of the character set and indicating relative positioning of ones of the plurality of keys useful as the second input to create the unique adjacent key pair sequence respectively associated with the available ones of the letters of the character set.

12. A character entry and display method for an electronic device comprising:
providing a keypad having a plurality of keys;
providing a processor connected to the keypad;
providing a memory connected to the processor which stores a plurality of characters comprising a plurality of letters, and which stores a unique key sequence identifier for each of the plurality of characters, wherein each of the plurality of letters corresponds to a unique one of a plurality of adjacent key pair sequences, and wherein the plurality of letters comprise a complete language letter set;
providing a display connected to the processor;
receiving with the processor the plurality of adjacent key pair sequences, wherein each of the plurality of adjacent key pair sequences comprises a consecutive input from two adjacent ones of the plurality of keys;
associating with the processor the plurality of letters respectively with the plurality of adjacent key pair sequences; and
displaying with the display the plurality of letters respectively associated with the plurality of adjacent key pair sequences.

13. The method of claim 12, further comprising:
providing the plurality of characters with a plurality of non-letter characters;
associating with the processor the plurality of non-letter characters respectively with the plurality of adjacent key pair sequences; and
displaying with the display the plurality of non-letter characters respectively associated with the plurality of adjacent key pair sequences.

14. The method of claim 12, further comprising providing the plurality of letters of the complete language letter set as A, B, C, D, E, F, G, H, I, J, K, L, M, N, O, P, Q, R, S, T, U, V, W, X, Y, and Z.

15. The character entry and display method of claim 14, further comprising:
receiving with the processor a unique diagonally adjacent key pair sequence for each of the B, E, H, K, N, Q, R, U, X, and Y, wherein each of the unique diagonally adjacent key pair sequences comprises a consecutive input from two diagonally adjacent ones of the plurality of keys;
associating with the processor the B, E, H, K, N, Q, R, U, X, and Y respectively with the unique diagonally adjacent key pair sequences; and
displaying with the display the B, E, H, K, N, Q, R, U, X, and Y respectively associated with the unique diagonally adjacent key pair sequences.

16. The character entry and display method of claim 14, further comprising:
receiving with the processor a unique vertically adjacent key pair sequence for each of the F, G, O, P, and Z, wherein each of the unique vertically adjacent key pair sequences comprises a consecutive input from two vertically adjacent ones of the plurality of keys;
associating with the processor the F, G, O, P, and Z respectively with the unique vertically adjacent key pair sequences; and
displaying with the display the F, G, O, P, and Z respectively associated with the unique vertically adjacent key pair sequences.

17. The character entry and display method of claim 14, further comprising:
receiving with the processor a unique horizontally adjacent key pair sequence for each of the A, C, D, I, J, L, M, S, T, V, and W, wherein each of the unique horizontally adjacent key pair sequences comprises a consecutive input from two horizontally adjacent ones of the plurality of keys;
associating with the processor the A, C, D, I, J, L, M, S, T, V, and W respectively with the unique horizontally adjacent key pair sequences; and
displaying with the display the A, C, D, I, J, L, M, S, T, V, and W respectively associated with the unique horizontally adjacent key pair sequences.

18. The method of claim 12, further comprising providing the keypad with the plurality of keys arranged as a standard 3×4 key array standard telephone keypad, whereby the keypad includes a 1 key, a 2 key, a 3 key, a 4 key, a 5 key, a 6 key, a 7 key, an 8 key, a 9 key, a * key, a 0 key, and a # key.

19. A character entry and display device comprising:
a 3×4 key standard telephone keypad comprising a 1 key, a 2 key, a 3 key, a 4 key, a 5 key, a 6 key, a 7 key, an 8 key, a 9 key, and a 0 key;
a processor connected to the keypad configured to receive a plurality of adjacent key pair sequences, wherein each of the plurality of adjacent key pair sequences comprises a consecutive input from two adjacent ones of the plurality of keys;
a memory connected to the processor which stores a plurality of characters comprising a plurality of letters, and which stores a unique key sequence identifier for each of the plurality of characters, wherein each of the plurality of letters corresponds to one of a plurality of adjacent key pair sequences, and wherein the plurality of letters comprise a complete language letter set; and wherein the processor is configured to associate the plurality of letters respectively with the plurality of adjacent key pair sequences; and
a display connected to the processor configured to display the plurality of letters respectively associated with the plurality of adjacent key pair sequences.

20. The character entry and display device of claim 19, wherein the 2 key is labeled ABC, the 3 key is labeled DEF, the 4 key is labeled GHI, the 5 key is labeled JKL, the 6 key is labeled MNO, the 7 key is labeled PQRS, the 8 key is labeled TUV, and the 9 key is labeled WXYZ.

21. The character entry and display device of claim 19, wherein the plurality of letters of the complete language letter set comprise A, B, C, D, E, F, G, H, I, J, K, L, M, N, O, P, Q, R, S, T, U, V, W, X, Y, and Z.

22. The character entry and display device of claim 21, wherein:
the processor is configured to receive a unique horizontally adjacent key pair sequence for each of the A, C, D, I, J, L, M, S, T, V, and W, wherein each of the unique horizontally adjacent key pair sequences comprises a consecutive input from two horizontally adjacent ones of the plurality of keys;
the processor is configured to associate the A, C, D, I, J, L, M, S, T, V, and W respectively with the unique horizontally adjacent key pair sequences; and
the processor is configured for displaying with the display the A, C, D, I, J, L, M, S, T, V, and W respectively associated with the unique horizontally adjacent key pair sequences.

23. The character entry and display device of claim 19, further comprising transmission and reception components for sending text messages comprising the plurality of letters.

24. A program product comprising a computer readable medium comprising instructions, the instructions being operable to enable an electronic device comprising a display and a 3×4 key array standard telephone keypad to perform a procedure comprising:
receiving a unique adjacent key pair sequence from the standard telephone keypad for each letter of a character set comprising A, B, C, D, E, F, G, H, I, J, K, L, M, N, O, P, Q, R, S, T, U, V, W, X, Y, and Z; and
displaying with the display a letter of the character set in response to receipt of each of the unique adjacent key pair sequences.

25. The program product of claim 24, the instructions being operable to enable the electronic device to perform the procedure further comprising:
receiving at least one of the unique adjacent key pair sequences as a consecutive input from a first key and a second key adjacent to the first key; and
displaying a cursor which indicates that the consecutive input from the second key is required.
